(19) United States
(12) Patent Application Publication
(10) Pub. No.: US 2016/0168707 A1
(43) Pub. Date: Jun. 16, 2016

(54) VAPOR DEPOSITION APPARATUS AND METHOD

(71) Applicant: SAMSUNG DISPLAY CO., LTD., Yongin-City (KR)

(72) Inventors: Choelmin JANG, Yongin-City (KR); Inkyo KIM, Yongin-City (KR); Sukwon JUNG, Yongin-City (KR); Myungsoo HUH, Yongin-City (KR)

(21) Appl. No.: 14/736,337

(22) Filed: Jun. 11, 2015

(30) Foreign Application Priority Data
Dec. 11, 2014 (KR) 10-2014-0178703

(51) Int. Cl. C23C 16/455; C23C 16/52; C23C 16/44; C23C 16/458; C23C 16/50

(52) U.S. Cl. CPC C23C 16/45574; C23C 16/4583; C23C 16/50; C23C 16/4408; C23C 16/52

(57) ABSTRACT

A vapor deposition apparatus includes a deposition unit having a plurality of nozzle parts sequentially arranged in a first direction and a plurality of exhaustion parts alternately arranged with the plurality of nozzle parts, a substrate mounting unit on which a substrate is mounted and which is reciprocally movable a plurality of times below the deposition unit along a straight line parallel to the first direction, and a control unit that controls movement of the substrate mounting unit. A start point of a reciprocal movement of the substrate mounting unit is variable for each reciprocal movement.

### CROSS-REFERENCE TO RELATED APPLICATION

Korean Patent Application No. 10-2014-0178703, filed on Dec. 11, 2014, in the Korean Intellectual Property Office, and entitled: “Vapor Deposition Apparatus and Method,” is incorporated by reference herein in its entirety.

### BACKGROUND

1. Field

Embodiments relate to a vapor deposition apparatus and method.

2. Description of the Related Art

Semiconductor elements, display apparatuses, and other electronic elements generally include a plurality of thin films. Various methods of forming such a plurality of thin films are used, and one of these methods is a vapor deposition method. In the vapor deposition method, one or more gases are used as raw materials for forming a thin film. The vapor deposition method may be a chemical vapor deposition (CVD) method, an atomic layer deposition (ALD) method, and other various methods.

An organic light-emitting display apparatus includes an intermediate layer having an emission layer between first and second electrodes facing each other. One or more various thin films, which may be formed by a vapor deposition process, may be further included in the organic light-emitting display apparatus.

### SUMMARY

Embodiments are directed to a vapor deposition apparatus including a deposition unit having a plurality of nozzle parts sequentially arranged in a first direction and a plurality of exhaustion parts alternately arranged with the plurality of nozzle parts, a substrate mounting unit on which a substrate is mounted and which is reciprocally movable a plurality of times below the deposition unit along a straight line parallel to the first direction, and a control unit that controls movement of the substrate mounting unit. A start point of a reciprocal movement of the substrate mounting unit is variable for each reciprocal movement.

The reciprocal movement start point may be one among preset positions and may be sequentially variable in the first direction and an opposite direction of the first direction. The preset positions may be spaced a predetermined distance apart from each other.

The number of preset positions may be from 5 to 20.

A distance between two adjacent preset positions may be about 0.5 to about 1.5 times a width of the exhaust part.

Any one of the two adjacent preset positions may be a start point of a reciprocal movement of the substrate mounting unit and the other one of the two adjacent present positions may be an end point of the reciprocal movement.

A reciprocally moving distance of the substrate mounting unit may be same for each reciprocal movement.

The substrate may move only within a region of the deposition unit.

The exhaust part may further include a purge part that sprays a purge gas towards the substrate mounting unit.

The plurality of nozzle parts may include first nozzle parts that sprays a first raw material gas and second nozzle parts that sprays a second raw material gas. The first nozzle parts and the second nozzle parts may be alternately arranged.

Each of the second nozzle parts may include a plasma generator, a surface surrounding the plasma generator, and a plasma generation space formed between the plasma generator and the surface.

Embodiments are also directed to a vapor deposition method including providing a substrate on a substrate mounting unit, locating the substrate mounting unit below a deposition unit, and spraying, by the deposition unit, a raw material gas towards the substrate mounting unit and repeatedly performing, by the substrate mounting unit, a reciprocal movement below the deposition unit. The deposition unit includes a plurality of nozzle parts sequentially arranged in a first direction and a plurality of exhaustion parts alternately arranged with the plurality of nozzle parts. The substrate mounting unit repeatedly performs the reciprocal movement along a straight line parallel to the first direction. A reciprocal movement start point of the substrate mounting unit varies for each reciprocal movement.

A start point and an end point of the each reciprocal movement may differ from each other. The end point of the each reciprocal movement may be a start point of a next reciprocal movement.

The reciprocal movement start point may be one among preset positions and may sequentially vary in the first direction or an opposite direction of the first direction.

A distance between two adjacent preset positions may be about 0.5 to about 1.5 times a width of the exhaust part.

The preset positions may be spaced a predetermined distance apart from each other. The number of preset positions may be from 5 to 20.

A reciprocally moving distance of the substrate mounting unit may be the same for each reciprocal movement.

The substrate may move only within a region of the deposition unit.

The exhaust part may further include a purge part that sprays a purge gas towards the substrate mounting unit.

The plurality of nozzle parts may include first nozzle parts and second nozzle parts alternately arranged. The first nozzle parts may spray a first raw material gas towards the substrate mounting unit. The second nozzle parts may spray a second raw material gas towards the substrate mounting unit.

Each of the second nozzle parts may include a plasma generator, a surface surrounding the plasma generator, and a plasma generation space formed between the plasma generator and the surface. The second raw material gas may be converted into a radical form in the plasma generation space.

### BRIEF DESCRIPTION OF THE DRAWINGS

Features will become apparent to those of skill in the art by describing in detail exemplary embodiments with reference to the attached drawings in which:

FIG. 1 illustrates a cross-sectional view of a vapor deposition apparatus according to an embodiment;

FIG. 2 illustrates a cross-sectional view for explaining a method of driving a substrate mounting unit in the vapor deposition apparatus of FIG. 1;

FIG. 3 illustrates a cross-sectional view of a modification example of the vapor deposition apparatus of FIG. 1;

FIG. 4 illustrates a cross-sectional view of another modification example of the vapor deposition apparatus of FIG. 1;

FIG. 5 illustrates a cross-sectional view of a second nozzle part in the vapor deposition apparatus of FIG. 4;

FIGS. 6 and 7 illustrate graphs of a comparison example and present examples showing a thickness distribution of a thin film deposited on a substrate by using a vapor deposition apparatus;

FIG. 8 illustrates a cross-sectional view of an organic light-emitting display apparatus manufactured by a vapor deposition apparatus according to an embodiment; and

FIG. 9 illustrates a magnified view of a portion F of FIG. 8.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

It will be understood that although the terms “first”, “second”, etc. may be used herein to describe various components, these components should not be limited by these terms. These components are only used to distinguish one component from another.

The terminology used in the application is used only to describe specific embodiments and does not have any intention to limit the inventive concept. An expression in the singular includes an expression in the plural unless they are clearly different from each other in context. In the application, it should be understood that terms, such as ‘include’ and ‘have’, are used to indicate the existence of an implemented feature, number, step, operation, element, part, or a combination thereof without excluding in advance the possibility of the existence or addition of one or more other features, numbers, steps, operations, elements, parts, or combinations thereof.

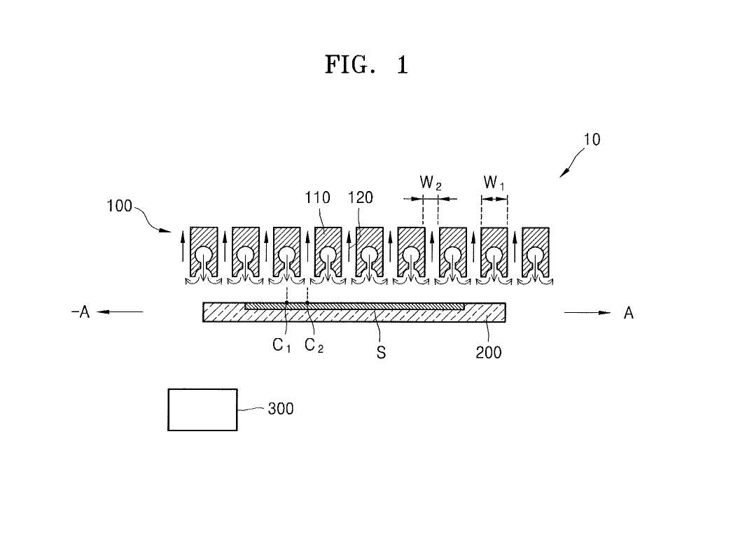

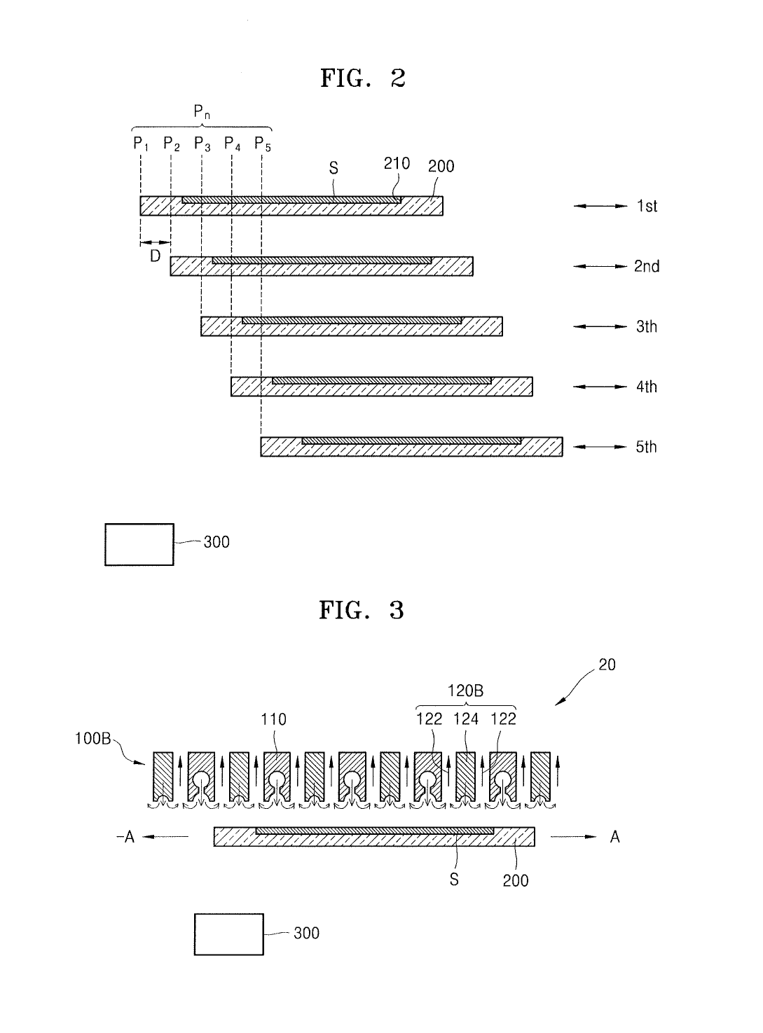

FIG. 1 illustrates a cross-sectional view of a vapor deposition apparatus 10 according to an embodiment, and FIG. 2 illustrates a cross-sectional view for explaining a method of driving a substrate mounting unit 200 in the vapor deposition apparatus 10 of FIG. 1.

Referring to FIGS. 1 and 2, the vapor deposition apparatus 10 may include a deposition unit 100 that sprays a raw material gas, the substrate mounting unit 200 on which a substrate S is mounted, and a control unit 300 that controls a motion of the substrate mounting unit 200. In addition, the vapor deposition apparatus 10 may include a chamber that accommodates the deposition unit 100, the substrate mounting unit 200, and the like.

The chamber may connect to a pump that controls a pressure atmosphere of a deposition process. The chamber may include one or more input/output ports that input and output the substrate S therethrough. In addition, the chamber may include a driving unit that moves the substrate mounting unit 200.

The deposition unit 100 may include a plurality of nozzle parts 110 arranged sequentially in a first direction A and a plurality of exhaust parts 120 alternately arranged with the plurality of nozzle parts 110.

Each of the plurality of nozzle parts 110 may continuously supply, towards the substrate mounting unit 200, one or more raw material gases that form a thin film on the substrate S.

The plurality of exhaust parts 120 may be connected to an exhaust pump and the like to suck and exhaust by-products separated from the substrate S, extra raw material gases, or the like.

The substrate mounting unit 200 may include a groove 210 in which the substrate S may be mounted. The substrate mounting unit 200 may transfer the substrate S into the inside of the chamber. The substrate mounting unit 200 may include a heater or a cooling apparatus that heat or cool the substrate S. The substrate mounting unit 200 may include a fixing apparatus for fixing the substrate S. The fixing apparatus may be a clamp, a pressing apparatus, an adhesive material, or other various fixing types.

The substrate mounting unit 200 may reciprocally move below the deposition unit 100 along a straight line parallel to the first direction A a plurality of times. A thickness of a thin film deposited on the substrate S may be adjusted according to the number of reciprocal movements.

The substrate mounting unit 200 may move only in a partial region of the deposition unit 100 instead of moving along a total length of the deposition unit 100. A moving distance of the substrate mounting unit 200 in the first direction A may be expressed as an integer times a distance corresponding to a width W1 of one nozzle part 110 and a width W2 of one exhaust part 120. Herein, the integer may be 1 or more.

For example, if the substrate mounting unit 200 repeatedly performs moving in the first direction A by the distance corresponding to the width W1 of one nozzle part 110 and the width W2 of one exhaust part 120 and returning in an opposite direction (−A) of the first direction A, a thin film may be formed over all of the substrate S. Compared with moving the substrate mounting unit 200 along the total length of the deposition unit 100, a length of the vapor deposition apparatus 10 may be reduced. When the substrate mounting unit 200 reciprocally moves, the substrate mounting unit 200 may move only within a region of the deposition unit 100.

The control unit 300 may control the substrate mounting unit 200 such that a reciprocal movement start point of the substrate mounting unit 200 varies for each reciprocal movement. In this case, a reciprocally moving distance of the substrate mounting unit 200 is the same for each reciprocal movement.

The reciprocal movement start point may be any one among preset positions Pn as shown in FIG. 2. According to repetition of the reciprocal movement of the substrate mounting unit 200, the reciprocal movement start point may be one of the preset positions Pn, which may sequentially vary in the first direction A or in the opposite direction −A of the first direction A.

For example, as shown in FIG. 2, if it is assumed that the number of preset positions Pn is 5 and the substrate mounting unit 200 reciprocally moves 5 times, a start point P1 of a first reciprocal movement 1st, a start point P2 of a second reciprocal movement 2nd, a third start point P3 of a third reciprocal movement 3th, a fourth start point P4 of a fourth reciprocal movement 4th, and a fifth start point P5 of a fifth reciprocal movement 5th may be gradually shifted positions of the preset positions Pn in the first direction A.

In addition, if the substrate mounting unit 200 reciprocally moves 6 times or more, the reciprocal movement start point of the substrate mounting unit 200 may sequentially vary from the fifth start point P5 of the fifth reciprocal movement 5th to the start point P1 of the first reciprocal movement 1st in the opposite direction −A of the first direction A, and thereafter, may sequentially vary from the start point P1 of the first reciprocal movement 1st to the fifth start point P5 of the fifth reciprocal movement 5th again.

That is, any one of adjacent two of the preset positions Pn may be a start point of a single reciprocal movement of the substrate mounting unit 200, and the other one may be an end point of the single reciprocal movement. In addition, the end point of the single reciprocal movement may be a start point of a consecutively next reciprocal movement.

If the substrate mounting unit 200 were to repeatedly perform the reciprocal movement with a same reciprocal movement start point and a same direction turning point, the thin film formed on the substrate S could have a non-uniform thickness. For example, if the plurality of nozzle parts 110 were to spray a raw material gas in a same way and if the substrate mounting unit 200 were to reciprocally move with a same amplitude, a plurality of regions having a width corresponding to the amplitude could be simultaneously deposited to form a thin film all over the substrate S, and in this case, unevenness could be formed at boundaries of the plurality of regions. According to the present embodiment, on the other hand, the reciprocal movement start point of the substrate mounting unit 200 may vary for each reciprocal movement. Accordingly, boundaries of a plurality of regions simultaneously deposited may be distributed for each reciprocal movement, and, a thin film deposited on the substrate S may have a uniform thickness distribution all over the substrate S, thereby easily improving characteristics of the thin film.

The number of preset positions Pn becoming the reciprocal movement start point may be 5 to 20. If the number of preset positions Pn is greater than 5, an effect of distributing boundaries of a plurality of regions simultaneously deposited may be achieved. If the number of preset positions Pn is less than 20, a great increase in the length of the vapor deposition apparatus 10 may be avoided. Thus, the reciprocal movement start point may sequentially vary within the preset positions Pn set to be 5 to 20.

In addition, the preset positions Pn may be formed to have a constant spacing distance D therebetween. The spacing distance D between adjacent two of the preset positions Pn may be about 0.5 to about 1.5 times the width W2 of the exhaust part 120.

As described above, a moving distance of the substrate mounting unit 200 in the first direction A during one reciprocal movement may be an integer times the distance corresponding to the width W1 of one nozzle part 110 and the width W2 of one exhaust part 120, although reciprocally moving distances for a region C1 below the nozzle part 110 from which the reciprocal movement starts and a region C2 below the exhaust part 120 from which the reciprocal movement starts are the same. Accordingly, a thin film may be formed with different thicknesses in the region C1 and the region C2.

A thin film formed on the substrate S reciprocally moving below the deposition unit 100 may be influenced by the exhaust part 120. The influence due to the exhaust part 120 in the formation of the thin film may be removed by changing the reciprocal movement start point by 0.5 times or more of the width W2 of the exhaust part 120 in each reciprocal movement. When the spacing distance D between adjacent two of the preset positions Pn is less than 1.5 times the width W2 of the exhaust part 120, an increase in the length of the vapor deposition apparatus 10 may be avoided. Thus, the spacing distance D between adjacent two of the preset positions Pn may be formed to be about 0.5 to about 1.5 times the width W2 of the exhaust part 120.

FIG. 3 illustrates a cross-sectional view of a vapor deposition apparatus 20 according to another embodiment.

Referring to FIG. 3, the vapor deposition apparatus 20 may include a deposition unit 100B that sprays a raw material gas, the substrate mounting unit 200 on which the substrate S is mounted, and the control unit 300 that controls a motion of the substrate mounting unit 200.

The deposition unit 100E may include the plurality of nozzle parts 110 arranged sequentially in the first direction A and a plurality of exhaust parts 120B alternately arranged with the plurality of nozzle parts 110.

Each of the plurality of nozzle parts 110 may continuously supply, towards the substrate mounting unit 200, one or more raw material gases to form a thin film on the substrate S.

Each of the plurality of exhaust parts 120B may include an exhaust nozzle 122 and a purge part 124. A purge gas may be injected via the purge part 124 towards the substrate mounting unit 200. The purge gas may be, for example, a gas that does not influence deposition, such as an argon gas, a nitrogen gas, or the like. Excess raw material gases on the substrate S that have not contributed to the formation of the thin film, by-products, or the like may be separated from the substrate by the purge gas and may be exhausted through the exhaust nozzle 122. Therefore, quality of the thin film to be formed on the substrate S may be improved.

In some implementations, the exhaust nozzle 122 may be formed at both sides of the purge part 124. In some implementations, the exhaust nozzle 122 may be formed at only one of the both sides of the purge part 124.

The substrate mounting unit 200 may reciprocally move beneath the deposition unit 100B in the first direction A and in the opposite direction −A of the first direction A for a plurality of times. The substrate mounting unit 200 may move only in a partial region of the deposition unit 100B instead of moving along a total length of the deposition unit 100B. The control unit 300 may control the substrate mounting unit 200 such that the reciprocal movement start point of the substrate mounting unit 200 may vary for each reciprocal movement of the substrate mounting unit 200. A length of the vapor deposition apparatus 20 may be reduced, and a thin film formed on the substrate S may have a uniform thickness distribution.

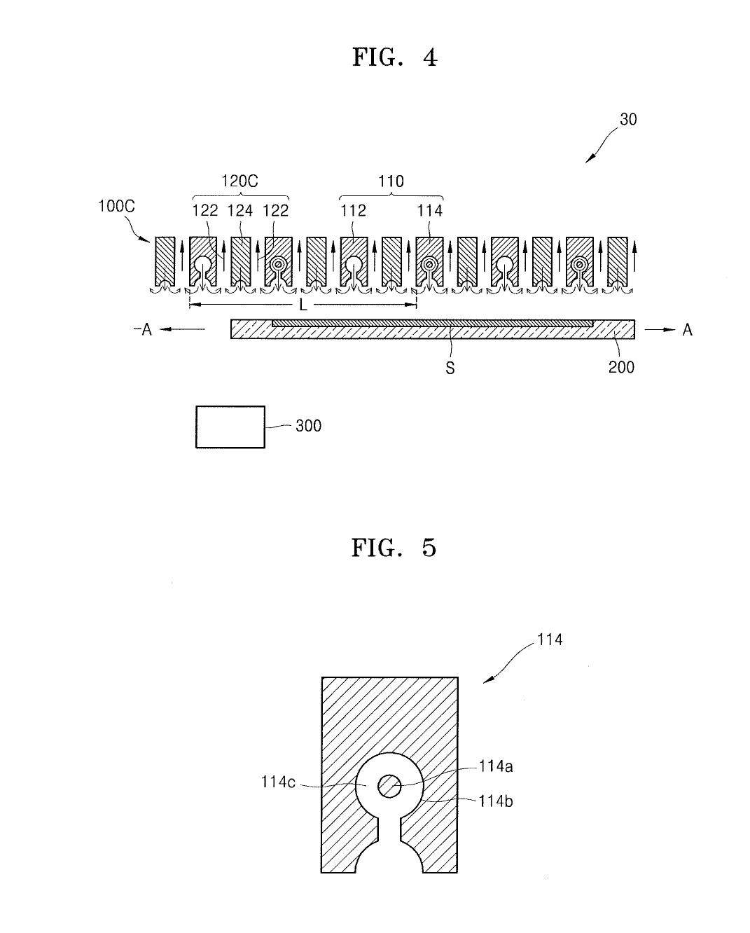

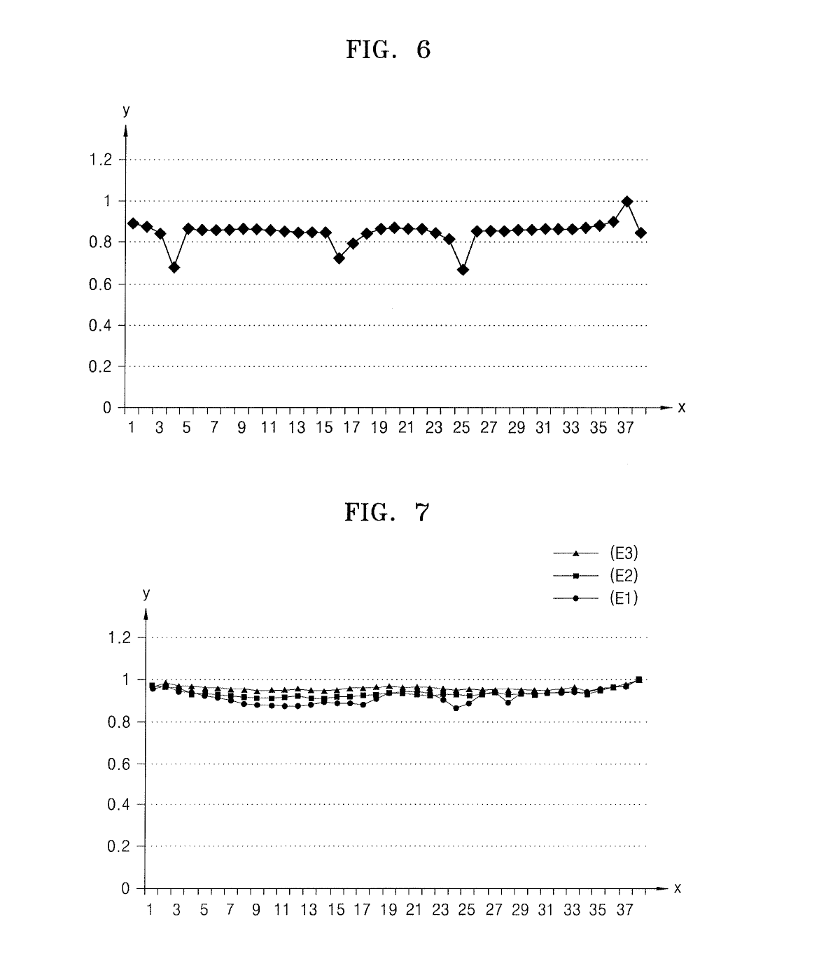

FIG. 4 illustrates a cross-sectional view of a vapor deposition apparatus 30 according to another embodiment, and FIG. 5 illustrates a cross-sectional view of a second nozzle part 114 in the vapor deposition apparatus 30 of FIG. 4. In addition, FIGS. 6 and 7 illustrate graphs of a comparison example and present examples showing a thickness distribution of a thin film deposited on the substrate S by using the vapor deposition apparatus 30.

Referring to FIGS. 4 and 5, the vapor deposition apparatus 30 may include a deposition unit 100C for spraying a raw material gas, the substrate mounting unit 200 on which the substrate S is mounted, and the control unit 300 for controlling a motion of the substrate mounting unit 200.

The deposition unit 100C may include the plurality of nozzle parts 110 arranged sequentially in the first direction A and a plurality of exhaust parts 120C alternately arranged with the plurality of nozzle parts 110.

The plurality of nozzle parts 110 may include first nozzle parts 112 for spraying a first raw material gas and second nozzle parts 114 for spraying a second raw material gas. The first nozzle parts 112 and the second nozzle parts 114 may be alternately arranged. That is, the deposition unit 100C may have a structure in which the first nozzle part 112, the exhaust part 120C, the second nozzle part 114, and the exhaust part 120C are repeatedly arranged.

The second nozzle part 114 may include a plasma generator 114a, a corresponding surface 114b surrounding the plasma generator 114a, and a plasma generation space 114c formed between the plasma generator 114a and the corresponding surface 114b.

In some implementation, the plasma generator 114a may be a cylindrically-shaped electrode to which a voltage is applied, and the corresponding surface 114b may be a grounded electrode. In some implementations, the plasma generator 114a may be grounded, and the voltage may be applied to the corresponding surface 114b. When a potential difference occurs between the plasma generator 114a and the corresponding surface 114b, plasma may be generated in the plasma generation space 114c, and the second raw material gas may be converted into a radical form in the plasma generation space 114c.

In some implementation, each of the plurality of exhaust parts 120C may include the exhaust nozzle 122 and the purge part 124. The exhaust nozzle 122 may be formed at both sides of the purge part 124. In some implementations, the exhaust nozzle 122 may be formed at only one of the both sides of the purge part 124.

The purge part 124 may inject a purge gas towards the substrate mounting unit 200. The purge gas may be, for example, a gas that does not influence deposition, such as an argon gas, a nitrogen gas, or the like. The purge part 124 may separate a portion that has not contributed to the formation of the thin film among the raw material gases sprayed on the substrate S, by-products. or the like from the substrate S and may prevent a mixing of the first raw material gas and the second raw material gas. The separated by-products, the excess raw material gases, or the like may be exhausted through the exhaust nozzle 122.

The substrate mounting unit 200 may reciprocally move below the deposition unit 100C in the first direction A and in the opposite direction −A of the first direction A a plurality of times. In this case, the substrate mounting unit 200 may move only in a partial region of the deposition unit 100C instead of moving along a total length of the deposition unit 100C. For example, a moving distance of the substrate mounting unit 200 in the first direction A may be an integer times a distance corresponding to a width of one exhaust part 120C. A length of the vapor deposition apparatus 30 may be reduced.

In addition, the control unit 300 may control the substrate mounting unit 200 such that the reciprocal movement start point of the substrate mounting unit 200 varies for each reciprocal movement of the substrate mounting unit 200. The reciprocal movement start point may be one among preset positions, which sequentially varies in the first direction A or in the opposite direction −A of the first direction A. The number of preset positions may be 5 to 20, and a spacing distance between two adjacent preset positions may be 0.5 to 1.5 times the width of one exhaust part 120C. Boundaries of a plurality of regions simultaneously deposited on the substrate S may be effectively distributed, thereby forming a thin film having an entirely uniform thickness distribution.

A process of forming a thin film on the substrate S by using the vapor deposition apparatus 30 of FIG. 4 will now described in brief. In addition, it will be described that a set moving distance L of the substrate mounting unit 200 corresponds to a whole width of the first nozzle part 112, the exhaust part 120C, the second nozzle part 114, the exhaust part 120C, the first nozzle part 112, and the exhaust part 120C.

The substrate S may be mounted on the substrate mounting unit 200. The substrate mounting unit 200 may be placed below the deposition unit 100C. The deposition unit 100C may spray the first and second raw material gases towards the substrate mounting unit 200. The substrate mounting unit 200 may repeatedly perform a reciprocal movement below the deposition unit 100C.

Below the first nozzle part 112, the first raw material gas may form a chemical adsorption layer and a physical adsorption layer on an upper surface of the substrate S. The physical adsorption layer, having a weak molecular bonding force among the adsorption layers formed on the upper surface of the substrate S, may be separated from the substrate S due to an injected purge gas and may be effectively removed from the substrate S by pumping through the exhaust nozzle 122.

The substrate mounting unit 200 may move in the first direction A. The substrate S may move below the second nozzle part 114. The second raw material gas may be injected onto the substrate S through the second nozzle part 114. The second raw material gas injected onto the substrate S through the second nozzle part 114 may be converted into a radical form in the plasma generation space 114C.

The second raw material gas may react with the chemical adsorption layer formed by the first raw material gas and already adsorbed on the substrate S or may replace a portion of the chemical adsorption layer and may finally form a desired deposition layer, e.g., a single atomic layer. An excess second raw material gas may remain on the substrate S by forming a physical adsorption layer on the substrate S. The excess second raw material gas may be removed from the substrate S through the exhaust part 120C located next to the second nozzle part 114 according to the movement of the substrate S.

The substrate mounting unit 200 may continuously move in the first direction A and may be located below the first nozzle part 114 again. A chemical adsorption layer and a physical adsorption layer due to the first raw material gas may be formed on an upper surface of the primarily formed deposition layer.

The substrate mounting unit 200 may move by the set moving distance L in the first direction A. The substrate mounting unit 200 may move in the opposite direction −A of the first direction A, thereby, forming two deposition layers on the substrate S. When the reciprocal movement is repeatedly performed, a desired number of deposition layers may be formed on the substrate S.

FIGS. 6 and 7 illustrate graphs of a comparison example and present examples showing a thickness distribution of a thin film deposited on the substrate S by using the vapor deposition apparatus 30, wherein an x axis indicates a width of the substrate S in the first direction A, and a y axis indicates a thickness distribution of the thin film deposited on the substrate S.

FIG. 6 illustrates a case where a reciprocal movement of the substrate mounting unit 200 moving by the set moving distance L (128 mm) in the first direction A and returning to the original position is repeatedly performed 200 times.

FIG. 7 illustrates a case where the substrate mounting unit 200 moving by the set moves distance L (128 mm) in the first direction A such that a reciprocal movement start point of the substrate mounting unit 200 varies for each reciprocal movement.

In more detail, E1 of FIG. 7 indicates a result obtained by repeatedly performing 20 times a case where the reciprocal movement start point of the substrate mounting unit 200 is shifted by 3 mm in the first direction 5 times and is thereafter shifted by 3 mm in the opposite direction −A of the first direction A 5 times.

E2 of FIG. 7 indicates a result obtained by repeatedly performing 10 times a case where the reciprocal movement start point of the substrate mounting unit 200 is shifted by 3 mm in the first direction 10 times and is thereafter shifted by 3 mm in the reverse direction −A of the first direction A 10 times.

E3 of FIG. 7 indicates a result obtained by repeatedly performing 5 times a case where the reciprocal movement start point of the substrate mounting unit 200 is shifted by 3 mm in the first direction 20 times and is thereafter shifted by 3 mm in the opposite direction −A of the first direction A 20 times.

As shown in FIGS. 6 and 7, the cases in FIG. 7 show an improved thickness uniformity of the thin film formed on the substrate S compared with the case in FIG. 6. This is because boundaries of a plurality of regions simultaneously deposited on the substrate S may be effectively distributed by changing the reciprocal movement start point of the substrate mounting unit 200 for each reciprocal movement as described above.

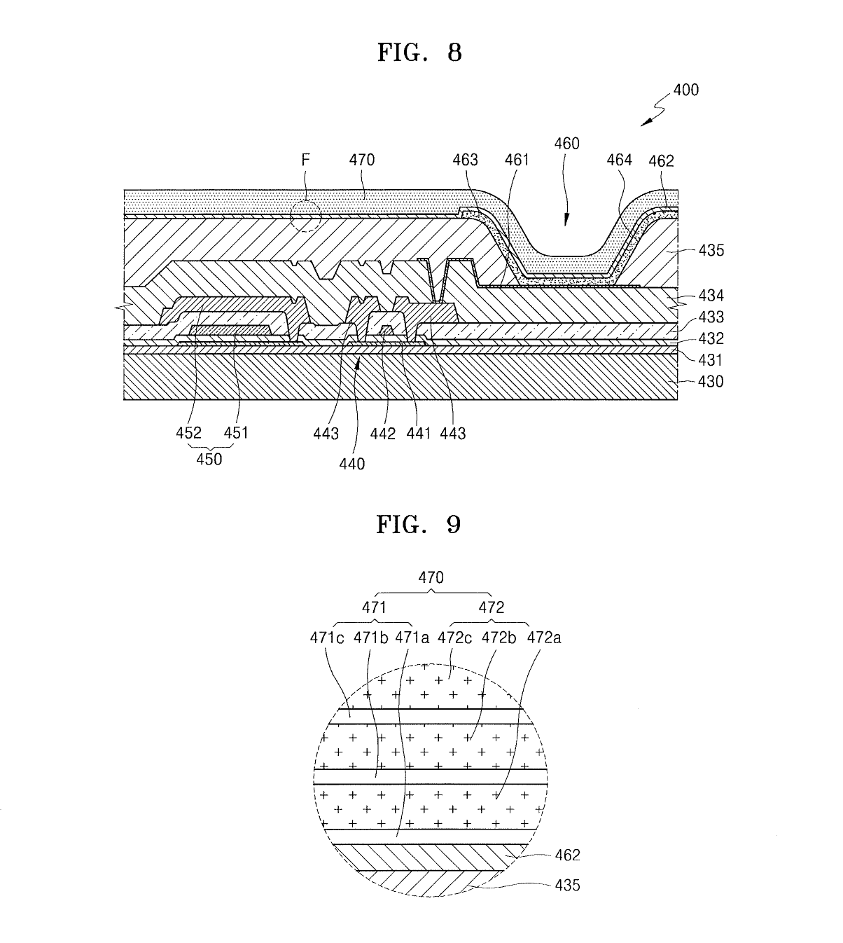

FIG. 8 illustrates a cross-sectional view of an organic light-emitting display apparatus 400 manufactured by the vapor deposition apparatus 10, 20, or 30 according to an embodiment, and FIG. 9 illustrates a magnified view of a portion F of FIG. 8.

Referring to FIGS. 8 and 9, the organic light-emitting display apparatus 400 may be formed on a substrate 430. The substrate 430 may be formed of a glass material a plastic material, or a metallic material.

A buffer layer 431 including an insulating material may be formed on the substrate 430 to provide a planarized surface and to help prevent the infiltration of moisture and foreign substances in a direction of the substrate 430.

A thin-film transistor (TFT) 440, a capacitor 450, and an organic light-emitting device (OLED) 460 may be formed on the buffer layer 431. The TFT 440 may include an active layer 441, a gate electrode 442, and source and drain electrodes 443. The OLED 460 includes a first electrode 461, a second electrode 462, and an intermediate layer 463. The capacitor 450 may include a first capacitor electrode 451 and a second capacitor electrode 452.

The active layer 441 formed in a predetermined pattern may be disposed on an upper surface of the buffer layer 431. The active layer 441 may include an inorganic semiconductor material such as silicon, an organic semiconductor material, or an oxide semiconductor material. The active layer 441 may be formed by injecting a p- or n-type dopant. A gate insulating layer 432 may be formed on the active layer 441. The gate electrode 442 may be formed on the gate insulating layer 432 such that the gate electrode 442 corresponds to the active layer 441. The first capacitor electrode 451 may be formed in the same layer as the gate electrode 442 and may be formed of the same materials as that of the gate electrode 442.

An interlayer insulating layer 433 may be formed to cover the gate electrode 442. The source and drain electrodes 443 may be formed on the interlayer insulating layer 433 such that the source and drain electrodes 443 respectively contact predetermined regions of the active layer 441. The second capacitor electrode 452 may be formed in the same layer as the source and drain electrodes 443. The second capacitor electrode 452 may be formed of the same material as that of the source and drain electrodes 443.

A passivation layer 434 may be formed to cover the source and drain electrodes 443. A separate insulating layer may be further formed on the passivation layer 434 to planarize the TFT 440.

The first electrode 461 may be formed on the passivation layer 434. The first electrode 461 may be formed such that the first electrode 461 is electrically connected to any one of the source and drain electrodes 443. A pixel-defining layer 435 may be formed to cover the first electrode 461. A predetermined opening 464 may be formed in the pixel-defining layer 435, and the intermediate layer 463 including an organic emission layer may be formed within a region limited by the opening 464. The second electrode 462 may be formed on the intermediate layer 463.

An encapsulation layer 470 may be formed on the second electrode 462. The encapsulation layer 470 may include an organic material or an inorganic material or may have a structure in which the organic material and the inorganic material are alternately stacked.

The encapsulation layer 470 may be formed using the vapor deposition apparatus 10, 20, or 30 described above. A desired layer may be formed by passing the substrate 430 on which the second electrode 462 is formed through the vapor deposition apparatus 10, 20, or 30.

For example, the encapsulation layer 470 may include an inorganic layer 471 and an organic layer 472, wherein the inorganic layer 471 includes a plurality of layers 471a, 471b, and 471c, and the organic layer 472 includes a plurality of layers 472a, 472b, and 472c. The plurality of layers 471a, 471b, and 471c of the inorganic layer 471 may be formed using the vapor deposition apparatus 10, 20, or 30.

In some implementations, the buffer layer 431, the gate insulating layer 432, the interlayer insulating layer 433, the passivation layer 434, the pixel-defining layer 435, and/or other insulating layers of the organic light-emitting display apparatus 400 may be formed using the vapor deposition apparatus 10, 20, or 30.

In addition, the active layer 441, the gate electrode 442, the source and drain electrodes 443, the first electrode 461, the intermediate layer 463, the second electrode 462, and/or other various thin films may also be formed using the vapor deposition apparatus 10, 20, or 30.

As described above, according to the one or more of the above exemplary embodiments, a length of a vapor deposition apparatus may be reduced, and characteristics of a formed thin film may be easily improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. A vapor deposition apparatus, comprising:
a deposition unit having a plurality of nozzle parts sequentially arranged in a first direction and a plurality of exhaustion parts alternately arranged with the plurality of nozzle parts;
a substrate mounting unit on which a substrate is mounted and which is reciprocally movable a plurality of times below the deposition unit along a straight line parallel to the first direction; and
a control unit that controls movement of the substrate mounting unit,
wherein a start point of a reciprocal movement of the substrate mounting unit is variable for each reciprocal movement.

2. The vapor deposition apparatus as claimed in claim 1, wherein
the reciprocal movement start point is one among preset positions and is sequentially variable in the first direction and an opposite direction of the first direction, and
the preset positions are spaced a predetermined distance apart from each other.

3. The vapor deposition apparatus as claimed in claim 2, wherein the number of preset positions is from 5 to 20.

4. The vapor deposition apparatus as claimed in claim 2, wherein a distance between two adjacent preset positions is about 0.5 to about 1.5 times a width of the exhaust part.

5. The vapor deposition apparatus as claimed in claim 4, wherein any one of the two adjacent preset positions is a start point of a reciprocal movement of the substrate mounting unit and the other one of the two adjacent preset positions is an end point of the reciprocal movement.

6. The vapor deposition apparatus as claimed in claim 2, wherein a reciprocally moving distance of the substrate mounting unit is same for each reciprocal movement.

7. The vapor deposition apparatus as claimed in claim 2, wherein the substrate moves only within a region of the deposition unit.

8. The vapor deposition apparatus as claimed in claim 2, wherein the exhaust part further includes a purge part that sprays a purge gas towards the substrate mounting unit.

9. The vapor deposition apparatus as claimed in claim 8, wherein;
the plurality of nozzle parts include first nozzle parts that sprays a first raw material gas and second nozzle parts that sprays a second raw material gas, and
the first nozzle parts and the second nozzle parts are alternately arranged.

10. The vapor deposition apparatus as claimed in claim 9, wherein each of the second nozzle parts includes a plasma generator, a surface surrounding the plasma generator, and a plasma generation space formed between the plasma generator and the surface.

11. A vapor deposition method, comprising:
providing a substrate on a substrate mounting unit;
locating the substrate mounting unit below a deposition unit; and
spraying, by the deposition unit, a raw material gas towards the substrate mounting unit and repeatedly performing, by the substrate mounting unit, a reciprocal movement below the deposition unit,
wherein the deposition unit includes a plurality of nozzle parts sequentially arranged in a first direction and a plurality of exhaustion parts alternately arranged with the plurality of nozzle parts,
the substrate mounting unit repeatedly performs the reciprocal movement along a straight line parallel to the first direction, and
a reciprocal movement start point of the substrate mounting unit varies for each reciprocal movement.

12. The vapor deposition method as claimed in claim 11, wherein:
a start point and an end point of the each reciprocal movement differ from each other, and
the end point of the each reciprocal movement is a start point of a next reciprocal movement.

13. The vapor deposition method as claimed in claim 12, wherein the reciprocal movement start point is one among preset positions and sequentially varies in the first direction or an opposite direction of the first direction.

14. The vapor deposition method as claimed in claim 13, wherein a distance between two adjacent preset positions is about 0.5 to about 1.5 times a width of the exhaust part.

15. The vapor deposition method as claimed in claim 13, wherein;
the preset positions are spaced a predetermined distance apart from each other, and
the number of preset positions is from 5 to 20.

16. The vapor deposition method as claimed in claim 13, wherein a reciprocally moving distance of the substrate mounting unit is the same for each reciprocal movement.

17. The vapor deposition method as claimed in claim 13, wherein the substrate moves only within a region of the deposition unit.

18. The vapor deposition method as claimed in claim 13, wherein the exhaust part further includes a purge part that sprays a purge gas towards the substrate mounting unit.

19. The vapor deposition method as claimed in claim 18, wherein:
the plurality of nozzle parts includes first nozzle parts and second nozzle parts alternately arranged,
the first nozzle parts spray a first raw material gas towards the substrate mounting unit, and
the second nozzle parts spray a second raw material gas towards the substrate mounting unit.

20. The vapor deposition method as claimed in claim 19, wherein:
each of the second nozzle parts includes a plasma generator, a surface surrounding the plasma generator, and a plasma generation space formed between the plasma generator and the surface, and
the second raw material gas is converted into a radical form in the plasma generation space.
